(19) United States
(12) Patent Application Publication
(10) Pub. No.: US 2013/0192668 A1
(43) Pub. Date: Aug. 1, 2013

(54) COMBINED HEAT AND POWER SOLAR SYSTEM

(71) Applicant: Roland Winston, Merced, CA (US)

(72) Inventor: Roland Winston, Merced, CA (US)

(73) Assignee: The Regents of the University of California, Oakland, CA (US)

(21) Appl. No.: 13/819,632

(22) PCT Filed: Aug. 29, 2011
(86) PCT No.: PCT/US2011/049609

§ 371 Date: Apr. 16, 2013

Related U.S. Application Data
(60) Provisional application No. 61/378,301, filed on Aug. 30, 2010.

(51) Int. Cl. H01L 31/024

(52) U.S. Cl. CPC H01L 31/024
USPC 136/255; 136/259; 438/64

(57) ABSTRACT

An apparatus is disclosed for converting incident light to electrical energy and heat. the apparatus includes an evacuated enclosure having at least a portion for admitting incident light; and an absorber member disposed at least partially in said enclosure to receive incident light. The absorber includes a selective surface which converts a portion of the incident light to heat. The selective surface comprises a photovoltaic layer which converts a portion of the incident light to electrical energy. In some embodiments, the absorber includes an elongated inner tube having an outer surface including the selective surface.

### CROSS-REFERENCE TO RELATED APPLICATION

This application claims priority under 35 U.S.C. §119(e) to U.S. Provisional Application No. 61/378,301, filed Aug. 30, 2010, the contents of which is incorporated by reference in its entirety into the present application.

### BACKGROUND

The present disclosure relates generally to the field of generating heat and electrical power from incident light, e.g. solar light.

The utilization of renewable energy sources is becoming popular as a way to reduce the dependence on fossil fuels and to decrease the emissions of pollutants and green-house gases into the atmosphere. Solar thermal systems provide the capability of generating heat, electric power, and/or cooling in a sustainable way and for a variety of applications due to the relatively large range of temperatures that different collector configurations can provide. Readily available in the market, solar collectors vary in performance depending on their design. The effective transfer of the heat obtained from the sun to the heat-transfer fluid remains a subject of continued interest. Solar collectors may employ light concentrators to concentrate solar light onto the collector.

Solar electric generation systems provide the capability of generating electric power directly from sunlight using photovoltaic (PV) materials. PV devices employing light concentrators are referred to as concentrating photovoltaics (CPV). CPV systems employ sunlight concentrated onto photovoltaic surfaces for the purpose of electrical power production.

Typically, light concentrators are designed to receive light incident over a range of angles less than an acceptance angle at an aperture. The light is concentrated onto a region (e.g., on an absorber) with an area smaller than the area of the aperture. The ratio of the aperture area to the smaller area is known as the geometric concentration. The laws of thermodynamics set a theoretical upper bound, known in the art as the “thermodynamic limit,” to the concentration for a given concentrator configuration. Many types of solar concentrators have been studied including reflective and refractive devices. Concentrators may be imaging or non imaging, and may be designed to correct for various types of optical aberration (spherical aberration, coma, astigmatism, chromatic aberration, etc.).

To effectively capture more of the available sunlight, concentrators and or the solar cells may be configured to move over the course of the day to follow or track the position of the sun as it changes over the course of the day and over the course of the year. Such tracking systems may move along a single axis or multiple axis and may be either passive systems or active systems that use electrical motors or other powered devices to move the solar energy system. However, tracking systems add an additional source of complexity and cost to a solar energy system.

### SUMMARY

The inventor has realized that an energy collector may be provided featuring a selective surface which includes a photovoltaic layer. The selective surface operates to convert incident light to both electrical energy and heat.

In one aspect, an apparatus is disclosed for converting incident light to electrical energy and heat. the apparatus includes an evacuated enclosure having at least a portion for admitting incident light; and an absorber member disposed at least partially in said enclosure to receive incident light. The absorber includes a selective surface which converts a portion of the incident light to heat. The selective surface comprises a photovoltaic layer which converts a portion of the incident light to electrical energy. In some embodiments, the absorber includes an elongated inner tube having an outer surface including the selective surface.

In one aspect, an apparatus is disclosed for converting incident light to electrical energy and heat, the apparatus including: an evacuated enclosure having at least a portion for admitting incident light; and an absorber member disposed at least partially in the enclosure to receive incident light, where the absorber includes a selective surface which converts a portion of the incident light to heat, and the selective surface includes a photovoltaic layer which converts a portion of the incident light to electrical energy.

In some embodiments, the incident light is solar light.

In some embodiments, the absorber includes an elongated inner tube having an outer surface including the selective surface.

In some embodiments, the elongated inner tube includes a rigid material tube, and the photovoltaic layer is formed on an outer surface of the tube.

In some embodiments, where the rigid material includes at least one selected from the list consisting of: glass, ceramic, aluminosilicate glass, borosilicate glass, flint glass, fluoride glass, fused silica glass, silicate glass, soda lime glass, and quartz glass.

In some embodiments, the evacuated enclosure includes an elongated outer tube disposed about the inner tube and having at least a portion which admits incident light onto the outer surface of the inner tube.

In some embodiments, the elongated inner tube includes at least one selected from the list consisting of: glass, ceramic, aluminosilicate glass, borosilicate glass, flint glass, fluoride glass, fused silica glass, silicate glass, soda lime glass, and quartz glass.

In some embodiments, the selective surface has an absorptivity to solar light of at least about 0.75 at an operating temperature.

In some embodiments, the selective surface has an absorptivity to solar light of at least about 0.9 at an operating temperature.

In some embodiments, the selective surface has an absorptivity to solar light of at least about 0.95 at an operating temperature.

In some embodiments, the selective surface has an emissivity of less than about 0.25 for wavelengths greater than 700 nm at an operating temperature.

In some embodiments, the selective surface has an emissivity of less than about 0.1 for wavelengths greater than 700 nm at an operating temperature.

In some embodiments, the selective surface has an emissivity of less than about 0.05 for wavelengths greater than 700 nm at an operating temperature.

In some embodiments, the photovoltaic layer includes a semiconductor having a band gap characterized by a band gap energy, where λg is the photon wavelength corresponding to the band gap energy.

In some embodiments, selective surface has an absorbtivity to incident light at wavelengths greater than λg of at least about 0.75 at an operating temperature.

In some embodiments, the selective surface has an absorbtivity to incident light at wavelengths greater than λg of at least about 0.9 at an operating temperature.

In some embodiments, the selective surface has an absorbtivity to incident light at wavelengths greater than λg of at least about 0.95 at an operating temperature.

In some embodiments, the selective surface has an emissivity of less than about 0.25 for wavelengths greater than λg at an operating temperature.

In some embodiments, the selective surface has an emissivity of less than about 0.9 for wavelengths greater than λg at an operating temperature.

In some embodiments, the selective surface has an emissivity of less than about 0.95 for wavelengths greater than λg at an operating temperature.

In some embodiments, the operating temperature is less than about 100 degrees Celsius.

In some embodiments, the operating temperature is less than about 200 degrees Celsius.

In some embodiments, the operating temperature is less than about 300 degrees Celsius.

In some embodiments, the operating temperature is less than about 500 degrees Celsius.

In some embodiments, the operating temperature is less than about 1000 degrees Celsius.

In some embodiments, the photovoltaic layer converts at least of the energy of the light incident on the layer has an external quantum efficiency of at least about 7.5%.

In some embodiments, the photovoltaic layer converts at least of the energy of the light incident on the layer has an external quantum efficiency of at least about 10%.

In some embodiments, the photovoltaic layer converts at least of the energy of the light incident on the layer has an external quantum efficiency of at least about 15%.

In some embodiments, the photovoltaic layer converts at least of the energy of the light incident on the layer has an external quantum efficiency of at least about 20%.

In some embodiments, the absorber includes a heat sink which transfers heat from of selective surface.

In some embodiments, the absorber includes at least one channel through which a working fluid flows to transfer heat from the selective surface.

Some embodiments include a heat exchanger which removes heat from the working fluid.

Some embodiments include at least one pump adapted to move the working fluid.

In some embodiments, the photovoltaic layer includes silicon

In some embodiments, the photovoltaic layer includes an active layer including at least one selected from the list consisting of: monocrystalline silicon, polycrystalline silicon, or amorphous silicon.

In some embodiments, the photovoltaic layer includes copper indium selenide.

In some embodiments, the photovoltaic layer includes copper indium galium selenide

In some embodiments, the photovoltaic layer includes cadmium telluride.

In some embodiments, the photovoltaic layer includes a semiconductor homojunction.

In some embodiments, the photovoltaic layer includes a semiconductor heterojunction.

In some embodiments, the photovoltaic layer includes a semiconductor p-n junction.

In some embodiments, the photovoltaic layer includes a semiconductor p-i-n junction.

In some embodiments, the photovoltaic layer includes multiple junctions.

In some embodiments, the photovoltaic layer includes a thin film formed on the outer surface of the inner tube.

In some embodiments, the thin film has a thickness of less than about 5 microns.

In some embodiments, the thin film has a thickness of less than about 1 microns.

In some embodiments, the thin film includes at least one photocell including a semiconductor active layer disposed between a first electrode and a second electrode.

In some embodiments, the first electrode is a back electrode formed on the outer surface of the inner tube, and the second electrode is a top electrode including a transparent conductive layer.

In some embodiments, the back electrode includes at least on from the list consisting of: copper, aluminum, molybdenum, titanium, carbon black.

In some embodiments, the transparent conductive layer includes a transparent conductive oxide.

In some embodiments, the back electrode is disposed about and surrounds at least a portion of the inner tube, the semiconductor active layer is disposed about and surrounds at least a portion of the back electrode, and the back electrode is disposed about and surrounds at least a portion of the semiconductor active layer.

Some embodiments include a concentrator disposed to concentrate the incident light onto the evacuated enclosure.

In some embodiments, the concentrator includes a compound parabolic concentrator.

In another aspect, a method is disclosed including: providing the apparatus for converting incident light to electrical energy and heat of any preceding claim; receiving incident light with the apparatus; and converting incident light to electrical energy and heat.

In another aspect, a method is disclosed of making an apparatus for converting incident light to electrical energy and heat, the method including: obtaining an first elongated tube; forming a selective surface on the tube which includes a photovoltaic layer; enclosing at least a portion of the first elongated tube in a second elongated tube; and substantially evacuating an enclosure formed between the first and second tubes. As used herein, the phrase “tube” is to be understood to include any elongated tubular member, e.g. having two, one, or no open ends.

As used herein the term “light” is to be understood to include electromagnetic radiation both within and outside of the visible spectrum, including, for example, ultraviolet and infrared radiation.

It is to be understood that both the foregoing general description and the following detailed description are exemplary and explanatory only, and are not restrictive of the invention as claimed.

### BRIEF DESCRIPTION OF THE DRAWINGS

These and other features, aspects, and advantages of the present invention will become apparent from the following description, appended claims, and the accompanying exemplary embodiments shown in the drawings, which are briefly described below.

FIG. 1 is a schematic diagram of an energy conversion system according to an exemplary embodiment.

FIG. 2A is a cross section of an energy collector for the system of FIG. 1 according to an exemplary embodiment.

FIG. 2B is a cross section of an energy collector for the system of FIG. 1 according to an exemplary embodiment.

FIG. 3 is a cross section of an energy collector for the system of FIG. 1 according to an exemplary embodiment.

FIG. 4 is a schematic diagram of a photovoltaic layer according to an exemplary embodiment.

FIG. 4A is a schematic diagram of a photovoltaic layer featuring a semiconductor junction according to an exemplary embodiment.

FIG. 5 illustrates the generation of photocurrent in a photovoltaic layer according to an exemplary embodiment.

FIG. 6 illustrates the response of a photovoltaic layer to the solar spectrum according to an exemplary embodiment.

FIGS. 7A & 7B are schematic diagrams of photovoltaic layers featuring multiple solar cells according to an exemplary embodiment.

FIG. 8A & 8B show an array of energy collectors with light concentrators according to an exemplary embodiment.

FIG. 9 is a flow diagram illustrating a method of making an energy collector according to an exemplary embodiment.

### DETAILED DESCRIPTION OF THE PREFERRED EMBODIMENTS

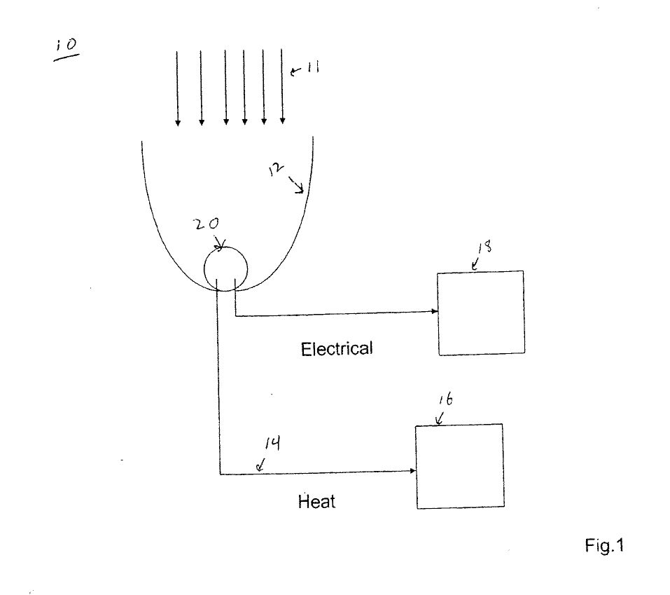

Referring to FIG. 1, a light energy conversion system 10 is shown according to an exemplary embodiment. The light conversion system 10 collects incident light energy 11 (in the examples provided the light energy is solar energy, but any other light may be used) and converts it to another form of energy that is useful to do work using an energy collector 20 (e.g., receiver, collector, etc.).

According to an exemplary embodiment, the energy collector 20 is a thermal vacuum tube that is configured to convert the solar energy to heat in a working fluid (e.g., water, oil, glycol, organic fluid, a molten salt, etc) or a mixture of working fluids. The working fluid is then circulated (e.g., with natural convection, with a pump, etc.) through a fluid system 14 to a device 16. In the device 16, the working fluid may do work (e.g. to drive a turbine, heat engine, etc.). In some embodiments, device 16 may include a heat exchanger which exchanges heat from the working fluid with another fluid to provide heated air or water (e.g., for residential use). The energy collector 20 is further configured to convert a portion of the incident radiation to electrical energy in an electrical system 18. For example, one or more surfaces of energy collector 20 may include a photovoltaic layer which generates electrical current in response to the incident light. As will be described in detail below, this photovoltaic layer may also serve as a selective surface, which promotes the absorption and conversion to heat of incident light 11, and reduces heat loss by emission of radiant heat.

Optionally, a light concentrator 12 may be used to concentrate light onto the collector 20 thereby increasing the amount of solar energy that may be converted by the energy collector 20. The concentrator 12 collects solar energy over a fairly large area (e.g., larger than the area of the area of the energy collector 20) and directs it through an output toward the energy collector 20. The concentrator 12 may be a parabolic or a non-imaging compound parabolic concentrators (e.g., CPC).

The concentrator may 12 be an elongated, trough-like body with an open end or aperture that receives light. The inner surface of the concentrator 12 reflects incident light such as sunlight onto the energy collector 20. In various embodiments, concentrator 12 may include a tracking system, e.g. to follow the movement of the sun across the sky. In other embodiments, concentrator 12 may concentrate incident light over a wide range of angles, thereby reducing or eliminating the need for tracking. In various embodiments, concentrator 12 may be of the types described in Roland Winston et al, Nonimaging Optics, Academic Press (Elsevier) 2005, and U.S. patent application Ser. No. 12/846710, filed Jul. 29, 2010; U.S. patent application Ser. No. 12/846729 filed Jul. 29, 2010; U.S. Pat. No. 12/036825, filed Feb. 25, 2008; U.S. patent application Ser. No. 11/970137, filed Jan. 7, 2008; U.S. patent application Ser. No. 11/949295, filed Dec. 3, 2007; and U.S. Pat. No. 11/932739, filed Oct. 31, 2007.

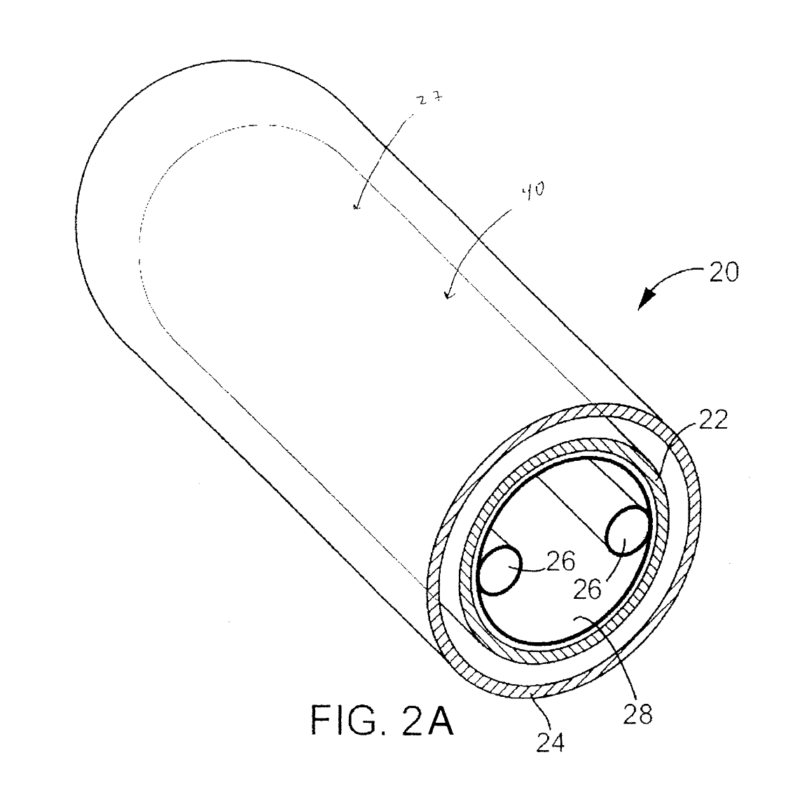

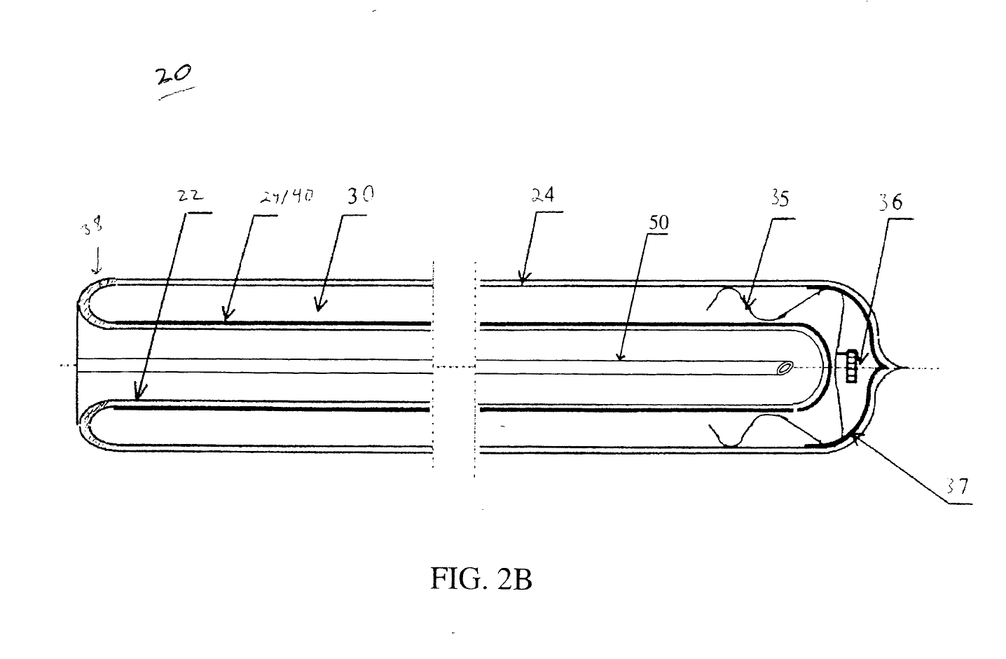

As shown in FIG. 2A, in one embodiment, the collector 20 (e.g., energy transducer, energy absorber, light absorber, etc.) comprises an inner tube 22 and an outer tube 24 with an inner diameter larger than the outer diameter of the inner tube 22. According to an exemplary embodiment, the inner tube 22 and the outer tube 24 are formed from a transparent material such as glass. In various embodiments, tubes 22 or 24 may be formed of materials including glass, ceramic, aluminosilicate glass, borosilicate glass, flint glass, fluoride glass, fused silica glass, silicate glass, soda lime glass, quartz glass, etc.

The inner tube 22 and the outer tube 24 are closed at one end to form a hemisphere and are fused together at the other end. The annular space between the inner tube 22 and the outer tube 24 is evacuated and sealed to form an evacuated enclosure about at least a portion of inner tube 22.

A working fluid is circulated through inner tube 22 to extract heat. As shown, the inner tube 22 houses one or more pipes 26 through which a working fluid is circulated. The pipes 26 are formed from a material with a relatively high thermal conductivity to facilitate the transfer of heat between inner tube 22 and the working fluid. The pipes may be formed, for example, from a metal such as aluminum, copper, brass, etc. According to an exemplary embodiment, the collector 20 includes a U-shape pipe that is connected to a manifold. The working fluid flows into the collector 20 along one arm and out of the collector 20 through the other arm. The pipes 26 may connect directly to a manifold by means of elongated piercings in a manifold wall through which the pipes 26 are inserted and bonded to the manifold wall by bracing, welding, etc. According to one exemplary embodiment, the inner tube 22 is about 1.5 meters in length and about 3 centimeters in diameter.

According to an exemplary embodiment, an thermally conductive fin 28 is mounted between the inner tube 22 and the pipes 26 to further facilitate the heat transfer to the heat-transfer fluid flowing in the pipes 26. The fin 28 may be ultrasound-welded or otherwise coupled to the pipes 26 at discrete locations within an external surface of the pipes 26. The pipes 26 and the fin 28 may be made of a selective material and/or coated with a selective coating that promotes absorption of solar radiation incident on the solar energy concentrator 10. The material or coating may have high absorptivity and low emissivity properties such that the coating promotes heat generation through absorption of incident light and limits radiant heat loss (e.g. by infrared emission). In other embodiments, the fin is omitted, and the pipes 26 or the working fluid may be in direct thermal contact with inner tube 22.

The solar energy absorbed by the collector 20 passes through the outer tube 24 onto the inner tube 22 to heat the absorber fin 28 and pipes 26 and the working fluid inside the pipes 26 with a radiation heat transfer. The at least partial vacuum between the inner tube 22 and the outer tube 24 reduces the energy lost to the outside environment from the pipes 26 due to conduction or convection. In some embodiments, and physical connections between the inner tube 22 and the outer tube 24 can be made using materials with very low thermal conductivity, thereby reducing loss of heat by conduction between the tubes.

Referring now to FIG. 2B, in another embodiment, the collector 20 (e.g., energy transducer, energy absorber, light absorber, etc.) comprises a transparent inner tube 22 and an outer tube 24 with an inner diameter larger than the outer diameter of the inner tube 22. The inner tube 22 and the outer tube 24 are closed at one end to form a hemisphere and are fused together at the other end. The annular space between the inner tube 22 and the outer tube 24 is evacuated and sealed to form an evacuated enclosure about at least a portion of inner tube 22.

The collector 20 further may comprise a Dewar collector in which the working fluid flows into the collector 20, e.g. from a manifold (not shown), through a feeder tube 50 that is open at the distal end. The working fluid exits the open end of the feeder tube 50, and then returns in the outside annular space between feeder tube 50 and inside wall of the inner tube 22, and finally back to the manifold. The feeder tube 50 may be formed from any suitable material, such as a metal, or glass. To reduce the manufacturing cost of the collector 20 in FIG. 2B, the feeder tube 50 may be formed from a relatively inexpensive material, such as glass, instead of a relatively expensive metal.

Typically the collector 20 may be oriented generally vertically, or may be tilted approximately at the latitude angle with the open end (e.g., where the inner tube 22 and the outer tube 24 are fused together) downward from the close end. In such a generally vertical orientation, the working fluid may be configured to drain from the collector at night so it is not being cooled in the lack of sunlight and losing energy. In other embodiments, the collector 20 may be oriented generally horizontally.

Other types of pipes or tubes may be used without limitation. For example, the collector 20 may house a counter-flow pipe design which utilizes a coaxial pipe in which the heat-transfer fluid flows through an internal pipe and returns through an external side that is attached to the fin 28.

The light absorbed by the collector 20 generally comprises a wide range of wavelengths of various intensities. At least portions of inner tube 22 may be coated with a selective coating 27. As described in detail below, the coating 27 has high absorptivity and low emissivity properties such that the coating promotes heat generation through absorption of incident light and limits radiant heat loss (e.g. by infrared emission).

According to an exemplary embodiment, the selective coating includes or consists of a thin film photovoltaic (PV) layer 40. PV layer 40 is applied to the outside of the inner tube 22 to increase the efficiency of the apparatus 10 by capturing energy and converting it to electrical energy in an electrical system 18. The PV layer 29 can include one or more PV cells which generate an electrical current in response to incident light 11. One or more electrically conductive leads, e.g. wires, electrodes, etc. (not shown) carry the generated photocurrent out of energy collector 22.

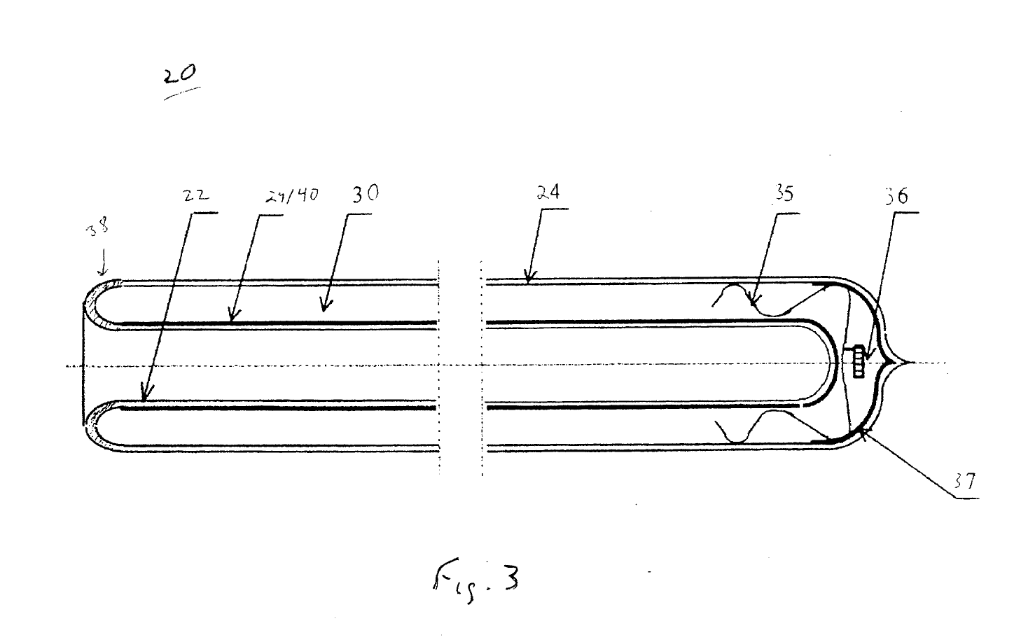

Referring to FIG. 3, in one embodiment, the collector 20 includes an integral member which includes the outer tube 24 disposed about the inner tube 22 to form the evacuated enclosure 30. The outer surface of the inner tube 22 is coated with the selective layer 29 which, as shown, is a the thin film PV layer 40 A retainer element 35 is provided in the evacuated enclosure 30 to mechanically support and maintain the position of the inner tube 22. The retainer element 35 may be made of a material with low thermal conductivity to reduce thermal loss by heat conduction from the inner tube 22 to the outer tube 24. Optionally, a low thermal conductivity end cap 38 may be provided to seal open ends of the inner and outer tubes 22, 24 while reducing or preventing thermal conduction between the tubes. In other embodiments, end cap 38 is omitted, and the ends of the inner tuber 22 and the outer tube 24 are fused together.

The evacuated enclosure 30 may include once or more getter elements used to maintain good vacuum within the enclosure. As is known in the art, a getter is a reactive material used for removing traces of gas from vacuum systems. Residual gas can be left in vacuums by inadequate vacuum pumps, or adsorbed gasses can be released after evacuation by the inner surfaces of the container. The getter may be a coating applied to a surface within the evacuated chamber. When molecules of residual gas strike the getter surface they chemically combine with the material, removing them from the evacuated space.

As shown, the evacuated enclosure 30 includes a getter 36 mounted on the retaining element 35. The getter 36 may be any suitable type of getter know in the art. In some embodiments, the getter 36 may be a nonevaporable getter suitable for operation at high temperature. In some embodiments, the nonevaporable getter may include a film of an alloy, e.g. including zirconium; which forms a passivation layer at room temperature which disappears when heated.

As shown, the evacuated enclosure 30 includes a flashed getter coating 37. The getter coating 37 is formed by arranging a reservoir of a volatile and reactive material inside the enclosure 30. Once the enclosure 30 evacuated and sealed, the material is heated, e.g. by RF induction heating, and evaporates, depositing itself on the walls to leave a coating. On exemplary flashed getter material is barium, but any other suitable material know in the art may be used, including aluminum, magnesium, calcium, sodium, strontium, cesium and phosphorus.

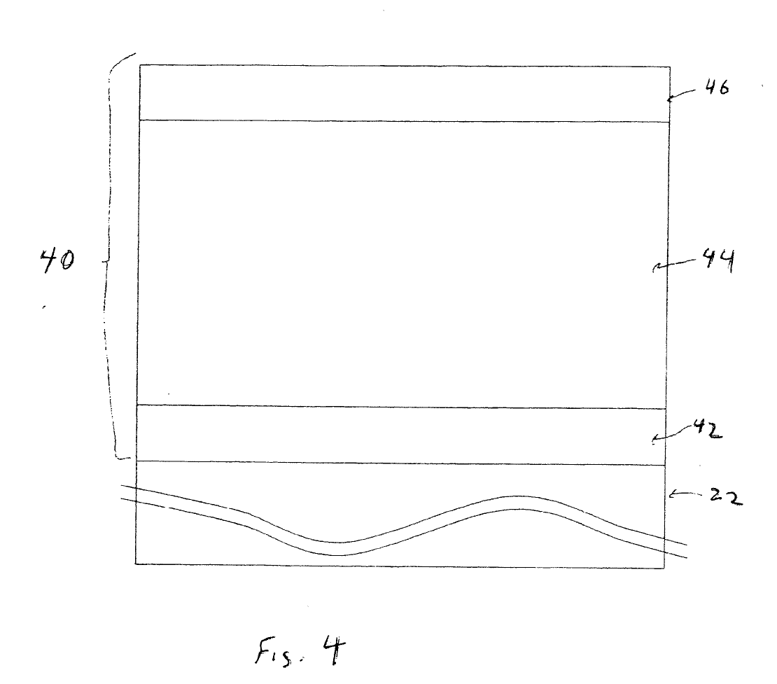

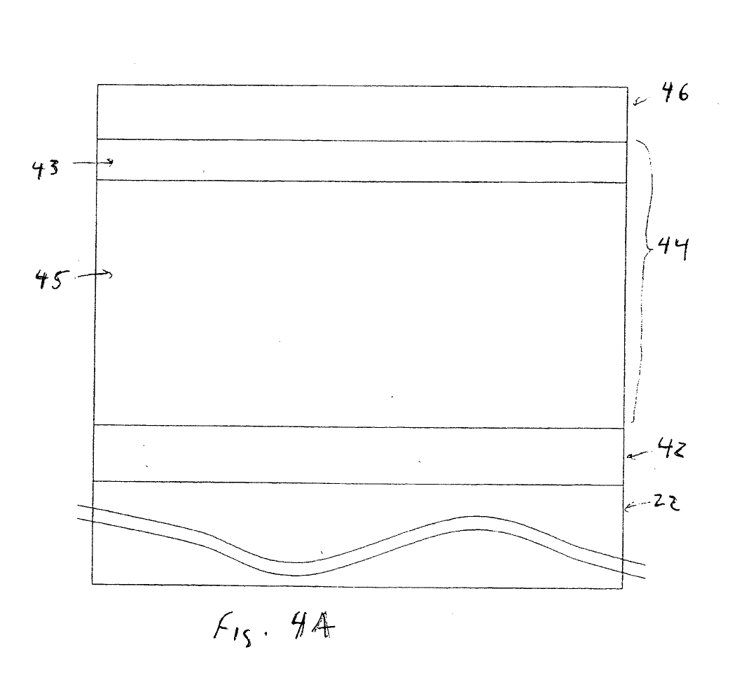

FIG. 4 shows a cross section of the thin film PV layer 40 formed on the outer surface of inner tube 22. As indicated by with a wavy line, the thin film PV layer is generally much thinner that the underlying inner tube 44. In some embodiments the PV layer 40 is less than about 10 microns thick, less than about 5 microns thick, less than about 1 micron thick, or even thinner. The photovoltaic layer 40 includes a back conductive electrode layer 42, a PV active layer 44, and a top electrode layer 46. The photovoltaic layer 40 may further include other layers such as an anti-reflective layer and/or protective layers.

In some embodiments, the top electrode 48 is a transparent electrode which admits the incident light 11 into the PV active layer 44. The top electrode layer 48 may be, for example, one or more transparent conductive layers, such as ZnO, indium tin oxide (ITO), Al doped ZnO (“AZO”) or a combination of higher resistivity AZO and lower resistivity ZnO, ITO or AZO layers. In some embodiments, the top electrode layer has a thickness less that the optical skin depth of the layer to the incident radiation (e.g. solar radiation).

The back electrode 42 may include any conductive layer which can be applied or formed on the inner tube 22. According to an exemplary embodiment, the substrate is metallic foil, such as copper or aluminum foil applied to the inner tube 22. In other embodiments, the back electrode 42 is a thin metallic layer formed (e.g. deposited by chemical vapor deposition, sputtering, or any other suitable technique) on the inner tube 22. For example, copper, aluminum, molybdenum, titanium, any other suitable conductive metal, a heavily doped electrically conductive semiconductor material, combinations of the foregoing, etc., may be used. In some embodiments, back conductive layer may include carbon black, e.g. mixed with an oxide or organic binder. As will be discussed in greater detail below, preferably, the back electrode 42 has is a high absorptivity and low emissivity material which operates as a thermal selective surface for incident light which is transmitted through the top electrode 42 and the PV active layer 44.

The PV active layer 40 is responsive to incident light to generate electrical energy. In typical embodiments, PV layer 40 includes one or more semiconductor junctions. In some embodiments, the junction may be a homojunction between layers of similar semiconducting material having different doping. In other embodiments, the junction may be a heterojunction between dissimilar materials (which may also be differently doped). In some embodiments, the PV layer 40 includes a plurality of junctions.

In some embodiments, the PV active layer 40 includes an interface between a p-doped and an n-doped region forming a p-n junction. In some embodiments, PV active layer 44 includes a wide, lightly doped ‘near’ intrinsic semiconductor region between a p-type semiconductor and an n-type semiconductor regions, referred to as a p-i-n junction. In some embodiments, the p-type and n-type regions of the p-i-n junction are t heavily doped, and may be used as ohmic contacts with electrode layers 42 and 46.

In some embodiments, PV active layer 44 includes a crystalline, polycrystalline, or amorphous semiconductor material. The semiconductor material may include a group IV elemental or compound semiconductor (e.g. Si, Ge, SiC, SiGe, etc.), a III-V semiconductor (e.g. GaAs, GaN, etc.), a II-V ternary, quaternary, or quinary alloy, a group II-VI semiconductor (CdSe, CdS, CdTe, etc.), a copper indium gallium selenide (CIGS) compound, or any other suitable semiconductor PV material.

Referring to FIG. 4A, in an exemplary embodiment, active layer 44 includes an n-type semiconductor layer 43 and a p-type semiconductor layer 45 forming a p-n junction 48. Together with the top and bottom electrodes 42, 46 form a photovoltaic cell which, in a circuit, generates an electrical current. Photons from the incident light 11 (e.g., in sunlight) with an energy above the band gap of the semiconductor material at the junction 48 strike the photovoltaic cell and create an electron-hole pair. The electron propagates through the n-type semiconductor 43 to top electrode 46 while a corresponding positively-charged “hole” propagates through the p-type semiconductor 45. Note that in other embodiments, the position of the p-type and n-type layers may be modified, e.g., reversed.

According to an exemplary embodiment, the p-type semiconductor 45 (e.g. absorber layer) is a copper indium gallium diselenide (CIGS) compound. According to another exemplary embodiment, the p-type semiconductor layer 45 is a cadmium telluride (CdTe) compound. According to still another exemplary embodiment, the p-type semiconductor layer 45 is an amorphous silicon material. CdTe has several advantages which make it desirable for use as a p-type semiconductor 45 in a PV active layer 44. CdTe can be adapted easily to achieve high absorptivity and low emissivity. CdTe can be deposited easily by manufacturers on large areas. Further, CdTe has direct energy band, about Eg=1.45 eV, with high theoretical efficiency 29% that it can absorb light with wavelength less than 856 nm. A CIGS compound has a structure that is similar to the structure of a CdTe compound. The energy band of a CIGS compound varies from 1.0 eV to 1.7 eV, which can be adjusted for the PV coating 40.

The n-type semiconductor layer 46 (e.g., window layer) is preferably thinner than the p-type semiconductor layer 44 and is generally highly transparent to the solar radiation. It is also referred to as a buffer layer because it may be configured to protect the p-n junction from damage induced by the deposition of the next layer. The n-type layer 46 may be, for example, CdS, ZnS, ZnSe, or another sulfide or selenide.

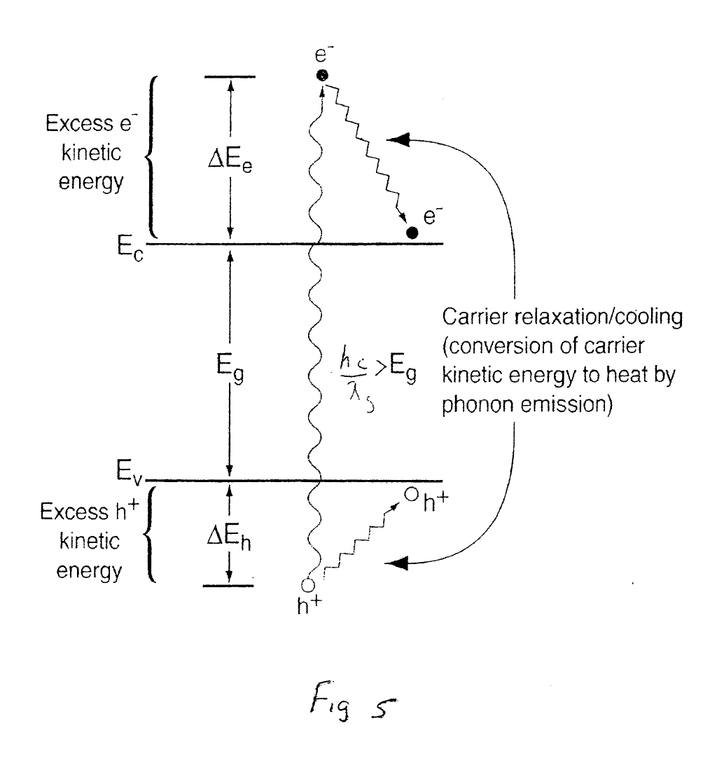

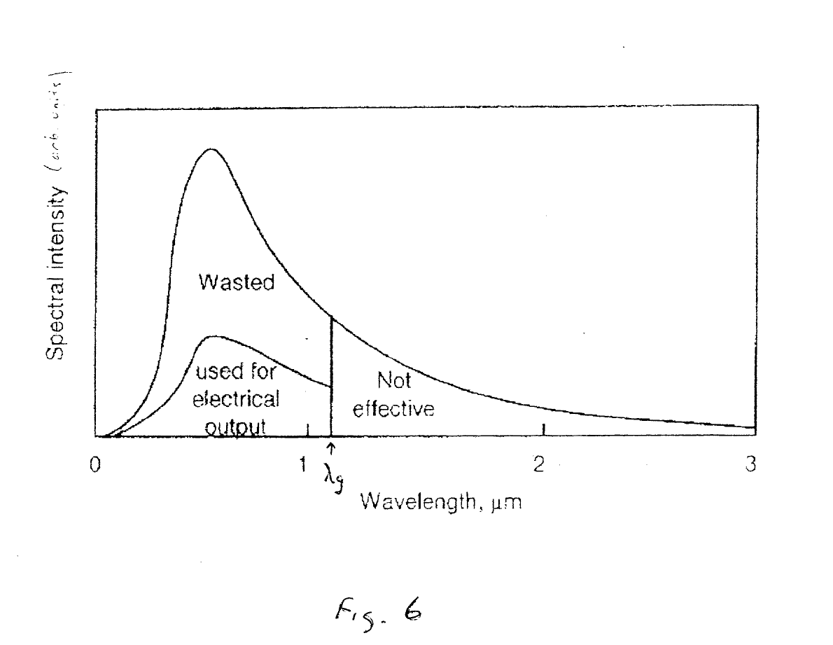

Referring to FIG. 5, in typical PV semiconductor materials, the electron-hole pair is created only if the energy of the photon is higher than the band gap Eg. This condition is met when the incident light has a wavelength less than a corresponding wavelength λ_{g}. The PV active layer 44 is generally transparent to lower energy photons with wavelengths greater than λ_{g}, (e.g., radiation towards the infrared side of the electromagnetic spectrum). For example, FIG. 6 shows a plot of spectral intensity versus wavelength for solar radiation. For the portion of the radiation having wavelengths above λ_{g} for PV active layer 44 (as show, approximately 1.1 microns), the PV active layer is ineffective for generating electrical output.

Accordingly, incident light with wavelengths greater than λ_{g} generally pass through the PV active layer 44 and impinge on the back contact layer 42. Thus, the back contact layer is preferably a low emittance material which has high absorptivity at wavelengths greater than λ_{g}, such that PV layer 40 will act as a selective layer. For example, the back contact 42 may include aluminum, copper, or any other suitable selective material. Accordingly, PV layer 40 acts to absorb light energy at wavelengths greater than λ_{g} and convert it to heat. PV layer 40 is on the inner tube 22 and thereby is in thermal contact with the working fluid. Thus, the working fluid acts as a heat sink, drawing the generated heat away from PV layer 40 and transferring the heat to device 16 to provide useful work.

Referring back to FIG. 5, for incident light having a photon energy greater than the bandgap Eg (i.e. photons with wavelengths less than λ_{g}) electron hole pairs are produce din PV active layer 44 with excess kinetics energy. As these charge carriers propagate through the PV active layer 44, this excess energy will be converted to heat (e.g. by phonon generation), and thus will not generate any electrical energy. Accordingly, as illustrated in FIG. 6, only a portion of the energy of the light incident upon PV active layer 44 is used to generate electrical output. The remainder of the energy is “wasted” by conversion to thermal energy. Further, this heating of PV active layer 44 will, in some embodiments, diminish the efficiency of photoconversion in the PV active layer 44. However, referring back to FIGS. 1 and 2, PV layer 40 is on the inner tube 22 and thereby is in thermal contact with the working fluid. Thus, the working fluid acts as a heat sink, drawing this heat away from the active PV layer 40 and transferring the heat to device 16 to provide useful work.

Accordingly, PV layer 40 works synergistically in collector 20 to provide increased efficiency for system 10. A portion of the incident light 11 is converted directly to electrical energy by PV layer 40. PV layer 40 also acts as a selective surface, such that a large portion of the remainder of the incident light is converted to heat, which is then transferred to the working fluid for productive use. Further, by removing heat from the PV layer 40, the working fluid prevents overheating of the layer, thereby avoiding heat related degradation of the PV photoconversion efficiency.

For example, as noted above, in typical embodiments, the incident light is solar light. By suitable choice of materials, the selective surface 27, including PV layer 40, may have an absorptivity to solar light of at least about 0.75, at least about 0.9, at least about 0.95, or even greater. In some embodiments, the selective surface may exhibit these absorptivities over substantially all wavelengths greater that λ_{g} (e.g. at all wavelengths greater than λ_{g} in the near IR and IR portions of the spectrum). The selective surface may have an emissivity of less than about 0.25, less than about 0.1, or less than about 0.05. In some embodiments, the surface may exhibit these emissivities at wavelengths in the visible, near IR, and/or IR, at wavelengths less than 700 nm, and or over substantially all wavelengths greater that λ_{g} (e.g. at all wavelength greater than λ_{g} in the near IR and IR portions of the spectrum). In various embodiments, the selective surface may exhibit the above absorptivity and emissivity properties at operating temperatures of less than about 100 degrees Celsius, less than about 200 degrees Celsius, less than about 300 degrees Celsius, less than about 500 degrees Celsius, less than about 1000 degrees Celsius, etc.

In various embodiments, the PV layer 40 has an external or an internal quantum efficiency of at least about 1%, at least about 5%, at least about 7.5%, at least about 10%, at least about 15%, at least about 20%, or more. External quantum efficiency (EQE) is the ratio of the number of charge carriers collected by a solar cell to the number of photons of a given wavelength impinging from outside. Internal quantum efficiency (IQE) is the ratio of the number of charge carriers collected by a solar cell to the number of photons of a given wavelength that impinge from the outside and are not reflected back by the cell, nor penetrate through. In various embodiments, the PV layer 40 may exhibit the above efficiencies over substantially all wavelengths less than λ_{g} (e.g. at all wavelengths greater than λ_{g} in the near IR and visible of the spectrum).

Note that in some embodiments, the entire PV layer 40 may be substantially transparent to light at wavelengths greater than λ_{g} (e.g. where back electrode 42 is a transparent conductor). In such cases, a separate selective surface layer (e.g. a copper or aluminum layer) may underlay the PV layer 40. This separate selective layer may be located on either the outer inner tube 22, or within inner tube 22 (e.g. located on an inner surface of the tube). In some embodiments, this separate selective layer may be a surface of or a coating upon fin 28.

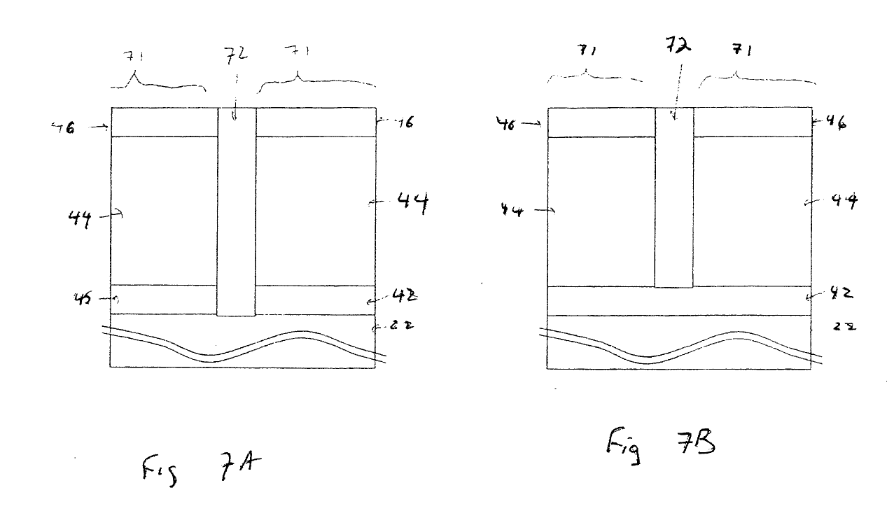

Referring to FIGS. 7A and 7B. in some embodiments, PV layer 40 may include more than one PV cell 71 (two are shown). Non-conductive elements 72 (e.g. made of adielectric, a non-conducting polymer, a non-conducting oxide, etc.) may be included in the layer to electrically isolate at least one cell from another cell. In FIG. 7A, the cells 71 are completely electrically isolated, while in FIG. 7B, the cells 71 share a common electrode. In some embodiments, two or more cells may be connected in a circuit, either in series or in parallel. The non-conductive elements 71 may be formed in PV layer 40 in any suitable pattern using any suitable techniques known in the art (e.g. photolithography).

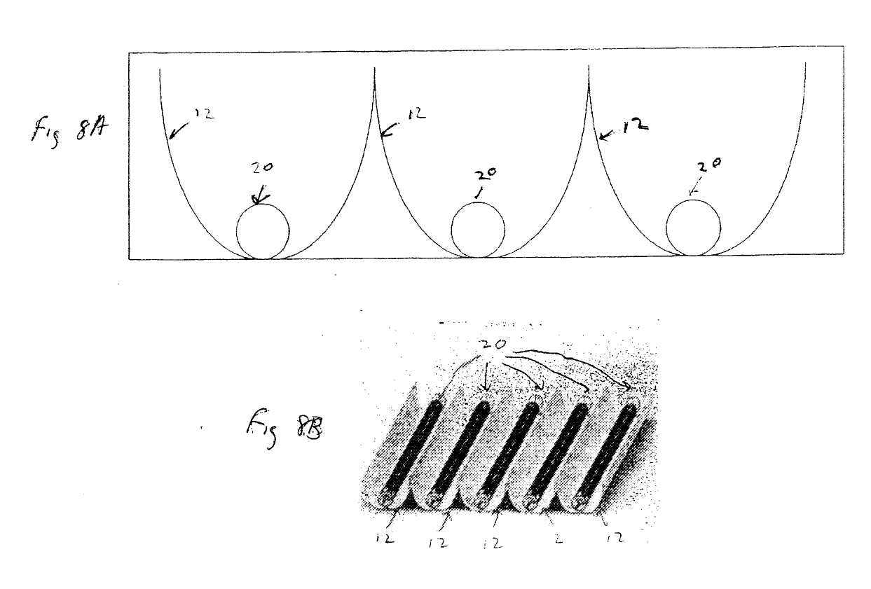

Referring to FIGS. 8A and 8B, in some embodiments, system 10 includes an array of energy collectors 20, one or more of which may be paired with a light concentrator 12. As shown, an array of tubular collectors 20 are each paired with a trough shaped non-tracking solar concentrator 12.

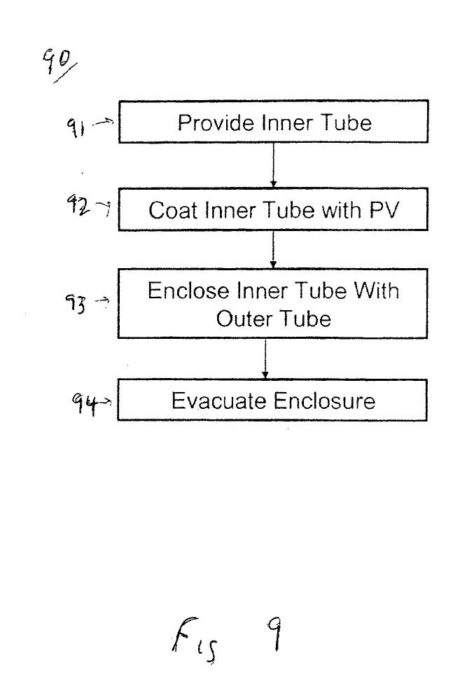

Referring to FIG. 9, and exemplary process 90 for fabricating an energy collector 20 of the type described above includes a step 91 of providing an inner glass (or other suitable material) inner tube 22.

In step 92, the selective PV layer 40 is coated onto the inner tube 22 using any suitable technique know in the art. For example, methods of PV deposition (e.g. amorphous silicon, CdTe, and/or CIGS deposition) including spraying, sputtering, layer deposition, roll to roll processing, etc. are well know in the art. Deposition process may be conducted under vacuum, or under non-vacuum conditions. For example, in some embodiments, a molybdenum layer may be deposited on inner tube 22, followed by a CIGS layer deposited using a spray technique. In some embodiments, a PV active layer (e.g. a CIGS layer) may be fabricated on a flexible substrate (e.g. a metal foil or polymer substrate) and subsequently applied to inner tube 22.

In step 93, inner tube 22 is at least partially enclosed within outer tube 24. In step 94, the enclosure surrounding inner tube 22 is evacuated.

While several examples of combined heat and solar power systems featuring straight, tubular energy collectors have been show, it is to be understood that alternative embodiments are within the scope of the disclosure. For example, in some embodiments, the tubular energy collectors may be curved, flattened, or have irregular shapes.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above.

All publications, patent applications, issued patents, and other documents referred to in this specification are herein incorporated by reference as if each individual publication, patent application, issued patent, or other document were specifically and individually indicated to be incorporated by reference in its entirety. Definitions that are contained in text incorporated by reference are excluded to the extent that they contradict definitions in this disclosure.

For the purposes of this disclosure and unless otherwise specified, “a” or “an” means “one or more.”

As used herein, the term “comprising” is intended to mean that the compositions and methods include the recited elements, but not excluding others. “Consisting essentially of” when used to define compositions and methods, shall mean excluding other elements of any essential significance to the combination for that intended purpose. “Consisting of” shall mean excluding more than trace elements of other ingredients and substantial method steps for making or using the concentrators or articles of this invention.

The construction and arrangements of the solar energy concentrator, as shown in the various exemplary embodiments, are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Some elements shown as integrally formed may be constructed of multiple parts or elements, the position of elements may be reversed or otherwise varied, and the nature or number of discrete elements or positions may be altered or varied. The order or sequence of any process, logical algorithm, or method steps may be varied or re-sequenced according to alternative embodiments. Other substitutions, modifications, changes and omissions may also be made in the design, operating conditions and arrangement of the various exemplary embodiments without departing from the scope of the present disclosure.

1. An apparatus for converting incident light to electrical energy and heat, the apparatus comprising:
an evacuated enclosure having at least a portion for admitting incident light; and
an absorber member disposed at least partially in said enclosure to receive incident light, wherein
the absorber comprises a selective surface which converts a portion of the incident light to heat, and
the selective surface comprises a photovoltaic layer which converts a portion of the incident light to electrical energy.

2. The apparatus of claim 1, wherein the incident light is solar light.

3. The apparatus of claim 1, wherein the absorber comprises an elongated inner tube having an outer surface comprising the selective surface.

4. That apparatus of claim 3, wherein the elongated inner tube comprises a rigid material tube, and the photovoltaic layer is formed on an outer surface of the tube.

5. The apparatus of claim 4, wherein the rigid material comprises at least one selected from the list consisting of: glass, ceramic, aluminosilicate glass, borosilicate glass, flint glass, fluoride glass, fused silica glass, silicate glass, soda lime glass, and quartz glass.

6. The apparatus of claim 3, wherein the evacuated enclosure comprises an elongated outer tube disposed about the inner tube and having at least a portion which admits incident light onto the outer surface of the inner tube.

7. The apparatus of claim 3, wherein the elongated inner tube comprises at least one selected from the list consisting of: glass, ceramic, aluminosilicate glass, borosilicate glass, flint glass, fluoride glass, fused silica glass, silicate glass, soda lime glass, and quartz glass.

8. The apparatus of claim 1, wherein the selective surface has an absorptivity to solar light of at least about 0.75 at an operating temperature.

9. The apparatus of claim 1, wherein the selective surface has an absorptivity to solar light of at least about 0.9 at an operating temperature.

10. The apparatus of claim 1, wherein the selective surface has an absorptivity to solar light of at least about 0.95 at an operating temperature.

11. The apparatus of claim 1, wherein the selective surface has an emissivity of less than about 0.25 for wavelengths greater than 700 nm at an operating temperature.

12. The apparatus of claim 1, wherein the selective surface has an emissivity of less than about 0.1 for wavelengths greater than 700 nm at an operating temperature.

13. The apparatus of claim 1, wherein the selective surface has an emissivity of less than about 0.05 for wavelengths greater than 700 nm at an operating temperature.

14. The apparatus of claim 1, wherein the photovoltaic layer comprises a semiconductor having a band gap characterized by a band gap energy, where λ_{g} is the photon wavelength corresponding to the band gap energy.

15. The apparatus of claim 14, wherein the selective surface has an absorbtivity to incident light at wavelengths greater than λ_{g} of at least about 0.75 at an operating temperature.

16. The apparatus of claim 14, wherein the selective surface has an absorbtivity to incident light at wavelengths greater than λ₉ of at least about 0.9 at an operating temperature.

17. The apparatus of claim 14, wherein the selective surface has an absorbtivity to incident light at wavelengths greater than λ_{g} of at least about 0.95 at an operating temperature.

18. The apparatus of claim 14 wherein the selective surface has an emissivity of less than about 0.25 for wavelengths greater than λ_{g} at an operating temperature.

19. The apparatus of claim 14 wherein the selective surface has an emissivity of less than about 0.9 for wavelengths greater than λ_{g} at an operating temperature.

20. The apparatus of claim 8 wherein the selective surface has an emissivity of less than about 0.95 for wavelengths greater than λ_{g} at an operating temperature.

21. The apparatus of claim 8, wherein the operating temperature is less than about 100 degrees Celsius.

22. The apparatus of claim 8, wherein the operating temperature is less than about 200 degrees Celsius.

23. The apparatus of claim 8, wherein the operating temperature is less than about 300 degrees Celsius.

24. The apparatus of claim 8, wherein the operating temperature is less than about 500 degrees Celsius.

25. The apparatus of claim 8, wherein the operating temperature is less than about 1000 degrees Celsius.

26. The apparatus of claim 1, wherein the photovoltaic layer converts at least of the energy of the light incident on the layer has an external quantum efficiency of at least about 7.5%.

27. The apparatus of claim 1, wherein the photovoltaic layer converts at least of the energy of the light incident on the layer has an external quantum efficiency of at least about 10%.

28. The apparatus of claim 1, wherein the photovoltaic layer converts at least of the energy of the light incident on the layer has an external quantum efficiency of at least about 15%.

29. The apparatus of claim 1, wherein the photovoltaic layer converts at least of the energy of the light incident on the layer has an external quantum efficiency of at least about 20%.

30. The apparatus of claim 1, wherein the absorber comprises a heat sink which transfers heat from of selective surface.

31. The apparatus of claim 1, wherein the absorber comprises at least one channel through which a working fluid flows to transfer heat from the selective surface.

32. The apparatus of claim 27, further comprising a heat exchanger which removes heat from the working fluid.

33. The apparatus of claim 27, further comprising at least one pump adapted to move the working fluid.

34. The apparatus of claim 1, wherein the photovoltaic layer comprises silicon

35. The apparatus of claim 30, wherein the photovoltaic layer comprises an active layer comprising at least one selected from the list consisting of: monocrystalline silicon, polycrystalline silicon, or amorphous silicon.

36. The apparatus of claim 1, wherein the photovoltaic layer comprises copper indium selenide.

37. The apparatus of claim 1, wherein the photovoltaic layer comprises copper indium galium selenide

38. The apparatus of claim 1, wherein the photovoltaic layer comprises cadmium telluride.

39. The apparatus of claim 1, wherein the photovoltaic layer comprises a semiconductor homojunction.

40. The apparatus of claim 1, wherein the photovoltaic layer comprises a semiconductor heterojunction.

41. The apparatus of claim 1, wherein the photovoltaic layer comprises a semiconductor p-n junction.

42. The apparatus of claim 1, wherein the photovoltaic layer comprises a semiconductor p-i-n junction.

43. The apparatus of claim 1, wherein the photovoltaic layer comprises multiple junctions.

44. The apparatus of claim 3, wherein the photovoltaic layer comprises a thin film formed on the outer surface of the inner tube.

45. The apparatus of claim 44, wherein the thin film has a thickness of less than about 5 microns.

46. The apparatus of claim 44, wherein the thin film has a thickness of less than about 1 microns.

47. The apparatus of claim 44, wherein the thin film comprises at least one photocell comprising a semiconductor active layer disposed between a first electrode and a second electrode.

48. The apparatus of claim 47, wherein the first electrode is a back electrode formed on the outer surface of the inner tube, and the second electrode is a top electrode comprising a transparent conductive layer.

49. The apparatus of claim 48, wherein the back electrode comprises at least on from the list consisting of: copper, aluminum, molybdenum, titanium, carbon black.

50. The apparatus of claim 47, or wherein the transparent conductive layer comprises a transparent conductive oxide.

51. The apparatus of claim 47, wherein:
the back electrode is disposed about and surrounds at least a portion of the inner tube, the semiconductor active layer is disposed about and surrounds at least a portion of the back electrode, and
the back electrode is disposed about and surrounds at least a portion of the semiconductor active layer.

52. The apparatus of claim 1, further comprising a concentrator disposed to concentrate the incident light onto the evacuated enclosure.

53. The apparatus of claim 52, wherein the concentrator comprises a compound parabolic concentrator.

54. A method comprising:
providing the apparatus for converting incident light to electrical energy and heat of claim 1;
receiving incident light with the apparatus;
converting incident light to electrical energy and heat.

55. A method of making an apparatus for converting incident light to electrical energy and heat, the method comprising:
obtaining an first elongated tube;
forming a selective surface on the tube which comprises a photovoltaic layer;
enclosing at least a portion of the first elongated tube in a second elongated tube; and
substantially evacuating an enclosure formed between the first and second tubes.
